(19) United States
(12) Patent Application Publication
(10) Pub. No.: US 2025/0150053 A1
(43) Pub. Date: May 8, 2025

(54) SOLIDLY-MOUNTED TRANSVERSELY-EXCITED FILM BULK ACOUSTIC RESONATORS AND FILTERS

(71) Applicant: Murata Manufacturing Co., Ltd., Nagaokakyo-shi (JP)

(72) Inventors: Gregory L. HEY-SHIPTON, Santa Barbara, CA (US); Neal FENZI, Santa Barbara, CA (US); Mike EDDY, Santa Barbara, CA (US); Ventsislav YANTCHEV, Sofia (BG)

(21) Appl. No.: 19/014,478

(22) Filed: Jan. 9, 2025

Related U.S. Application Data
(63) Continuation of application No. 17/558,090, filed on Dec. 21, 2021, now Pat. No. 12,224,732.
Application No. 17/558,090 is a continuation-in-part of application No. 16/896,147, filed on Jun. 8, 2020, now Pat. No. 11,264,966.
Application No. 16/896,147 is a continuation-in-part of application No. 16/779,306, filed on Jan. 31, 2020, now Pat. No. 11,165,407.
Application No. 16/779,306 is a continuation of application No. 16/438,141, filed on Jun. 11, 2019, now Pat. No. 10,601,392.
Application No. 16/438,141 is a continuation-in-part of application No. 16/230,443, filed on Dec. 21, 2018, now Pat. No. 10,491,192.
(60) Provisional application No. 63/251,459, filed on Oct. 1, 2021.
(60) Provisional application No. 63/000,006, filed on Mar. 26, 2020.
(60) Provisional application No. 62/753,809, filed on Oct. 31, 2018.
(60) Provisional application No. 62/818,564, filed on Mar. 14, 2019.
(60) Provisional application No. 62/685,825, filed on Jun. 15, 2018.
(60) Provisional application No. 62/701,363, filed on Jul. 20, 2018.
(60) Provisional application No. 62/741,702, filed on Oct. 5, 2018.
(60) Provisional application No. 62/748,883, filed on Oct. 22, 2018.
(60) Provisional application No. 62/753,815, filed on Oct. 31, 2018.

(51) Int. Cl. H03H 9/02; H03H 3/02; H03H 9/13; H03H 9/17; H03H 9/56

(52) U.S. Cl. CPC H03H 9/02228; H03H 3/02; H03H 9/02031; H03H 9/132; H03H 9/175; H03H 9/176; H03H 9/562; H03H 9/564; H03H 9/568; H03H 2003/025

(57) ABSTRACT

Resonator devices and filter devices are disclosed. A radio frequency filter includes substrate; a piezoelectric layer; a conductor pattern comprising a plurality of interdigital transducers (IDTs) on the piezoelectric layer; and an acoustic Bragg reflector between the substrate and the piezoelectric layer. The plurality of IDTs comprises a first IDT of first acoustic resonator and a second IDT of a second acoustic resonator. Moreover, a first thickness of the piezoelectric layer under the first IDT is greater than a second thickness of piezoelectric layer under the second IDT.

### CROSS REFERENCE TO RELATED APPLICATIONS

This application is a continuation of U.S. application Ser. No. 17/558,090, filed Dec. 21, 2021, which claims priority to U.S. Provisional Patent Application No. 63/251,459, filed Oct. 1, 2021, titled SOLIDLY MOUNTED MMW XBAR FILTERS. U.S. application Ser. No. 17/558,090 is a continuation-in-part of U.S. application Ser. No. 16/896,147, filed Jun. 8, 2020, now issued as U.S. Pat. No. 11,264,966, which claims priority to U.S. Provisional Patent Application No. 63/000,006, filed Mar. 26, 2020, titled SM-XBAR WITH DIAMOND LAYERS IN ACOUSTIC BRAGG REFLECTOR. U.S. application Ser. No. 16/896,147 is a continuation-in-part of U.S. application Ser. No. 16/779,306, now issued as U.S. Pat. No. 11,165,407, which is a continuation of U.S. application Ser. No. 16/438,141, filed Jun. 11, 2019, now issued as U.S. Pat. No. 10,601,392, which claims priority to U.S. Provisional Patent Application No. 62/753,809, filed Oct. 31, 2018, titled SOLIDLY MOUNTED SHEAR-MODE FILM BULK ACOUSTIC RESONATOR, and to U.S. Provisional Patent Application No. 62/818,564, filed Mar. 14, 2019, titled SOLIDLY MOUNTED XBAR. U.S. application Ser. No. 16/438,141 is a continuation-in-part of application Ser. No. 16/230,443, filed Dec. 21, 2018, now issued as U.S. Pat. No. 10,491,192, which claims priority from the following provisional applications: application 62/685,825, filed Jun. 15, 2018, entitled SHEAR-MODE FBAR (XBAR); application 62/701,363, filed Jul. 20, 2018, entitled SHEAR-MODE FBAR (XBAR); application 62/741,702, filed Oct. 5, 2018, entitled 5 GHZ LATERALLY-EXCITED BULK WAVE RESONATOR (XBAR); application 62/748,883, filed Oct. 22, 2018, entitled SHEAR-MODE FILM BULK ACOUSTIC RESONATOR; and application 62/753,815, filed Oct. 31, 2018, entitled LITHIUM TANTALATE SHEAR-MODE FILM BULK ACOUSTIC RESONATOR. All of these applications are incorporated herein by reference in their entireties.

### TECHNICAL FIELD

This disclosure relates to radio frequency filters using acoustic wave resonators, and specifically to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a pass-band or stop-band depend on the application. For example, a “pass-band” may be defined as a frequency range where the insertion loss of a filter is better than a defined value such as 1 dB, 2 dB, or 3 dB. A “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

RF filters typically require many design trade-offs to achieve, for each specific application, the best compromise between performance parameters such as insertion loss, rejection, isolation, power handling, linearity, size and cost. Specific design and manufacturing methods and enhancements can benefit simultaneously one or several of these requirements.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example at the RF module, RF transceiver, mobile or fixed sub-system, or network levels.

High performance RF filters for present communication systems commonly incorporate acoustic wave resonators including surface acoustic wave (SAW) resonators, bulk acoustic wave (BAW) resonators, film bulk acoustic wave resonators (FBAR), and other types of acoustic resonators. However, these existing technologies are not well-suited for use at the higher frequencies and bandwidths proposed for future communications networks.

The desire for wider communication channel bandwidths will inevitably lead to the use of higher frequency communications bands. Radio access technology for mobile telephone networks has been standardized by the 3GPP (3^{rd} Generation Partnership Project). Radio access technology for 5th generation (5G) mobile networks is defined in the 5G NR (new radio) standard. The 5G NR standard defines several new communications bands falling just below the lower edge of what is commonly termed “millimeter waves” (MMW). Three of these new communications bands are n257 (26.5 GHz to 29.5 GHZ), n258 (24.5 GHz to 27.5 GHz), and n261 (27.5 GHz to 28.35 GHz.) These bands will be collectively referred to herein as “27 GHz communications bands.” Bands n257, n258, and n261 use time-division duplexing (TDD), such that the same frequencies are used for both uplink and downlink transmissions. Bandpass filters for communications devices using TDD must be capable of handling the transmit power of the communications device.

The Transversely-Excited Film Bulk Acoustic Resonator (XBAR) is an acoustic resonator structure for use in microwave filters. The XBAR is described in patent U.S. Pat. No. 10,491,291, titled TRANSVERSELY EXCITED FILM BULK ACOUSTIC RESONATOR. An XBAR resonator comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, band-pass filters, duplexers, and multiplexers. XBARs are well suited for use in filters for communications bands with frequencies above 3 GHz.

A solidly-mounted transversely-excited film bulk acoustic resonator (SM-XBAR) is an acoustic resonator structure similar to an XBAR except that the thin piezoelectric layer is on an acoustic Bragg reflector rather than floating. SM-XBAR is described in U.S. Pat. No. 10,601,392, titled SOLIDLY-MOUNTED TRANSVERSELY-EXCITED FILM BULK ACOUSTIC RESONATOR.

### BRIEF DESCRIPTION OF THE DRAWINGS

FIG. 1 includes a schematic plan view and schematic cross-sectional views of a transversely-excited film bulk acoustic resonator (XBAR).

FIG. 2 includes a schematic plan view and a schematic cross-sectional view of a solidly-mounted transversely-excited film bulk acoustic resonator (SM XBAR).

FIG. 3 is an expanded schematic cross-sectional view of a portion of the SM XBAR of FIG. 2.

FIG. 4 is a graphic illustrating a shear primary acoustic mode in an SM XBAR.

FIG. 5 is an expanded schematic cross-sectional view of a portion of an exemplary SM XBAR.

FIG. 6 is a chart showing the dependence of the Q-factor of the SM XBAR of FIG. 5 on the number of layers in the acoustic Bragg reflector.

FIG. 7 is a graph showing the magnitude of admittance versus frequency for representative SM-XBARs.

FIG. 8 is a block diagram of a filter including eight SM XBARs.

FIG. 9A is a schematic cross-sectional view of a filter with a dielectric layer to set a frequency separation between shunt resonators and series resonators.

FIG. 9B is a schematic cross-sectional view of a filter with different piezoelectric diaphragm thicknesses to set a frequency separation between shunt resonators and series resonators.

FIG. 10 is a graph of input/output transfer function S(1,2) for a filter implemented with SM-XBARs.

FIG. 11 is a flow chart for a process to fabricate an SM-XBAR.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator.

### DETAILED DESCRIPTION

### Description of Apparatus

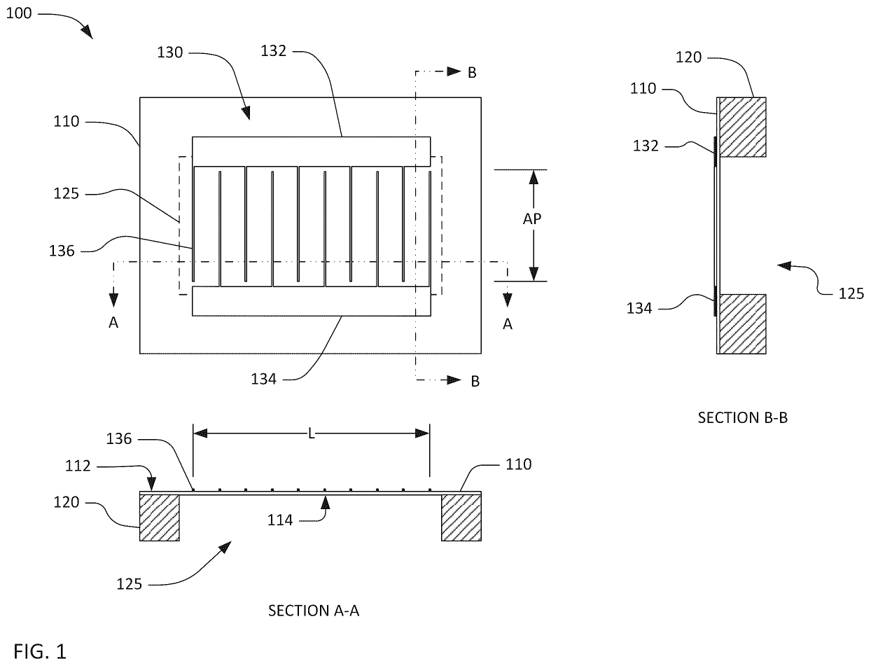

FIG. 1 shows a simplified schematic top view and orthogonal cross-sectional views of a transversely-excited film bulk acoustic resonator (XBAR) 100 as described in application Ser. No. 16/230,443, TRANSVERSELY-EXCITED FILM BULK ACOUSTIC RESONATOR. XBAR resonators such as the resonator 100 may be used in a variety of RF filters including band-reject filters, band-pass filters, duplexers, and multiplexers. XBARs are particularly suited for use in filters for communications bands with frequencies above 3 GHz.

The XBAR 100 is made up of a thin film conductor pattern formed on a surface of a piezoelectric plate 110 having parallel front and back surfaces 112, 114, respectively. The piezoelectric plate is a thin single-crystal layer of a piezoelectric material such as lithium niobate, lithium tantalate, lanthanum gallium silicate, gallium nitride, or aluminum nitride. The piezoelectric plate is cut such that the orientation of the X, Y, and Z crystalline axes with respect to the front and back surfaces is known and consistent. In the examples presented in this patent, the piezoelectric plates are Z-cut, which is to say the Z axis is normal to the surfaces. However, XBARs may be fabricated on piezoelectric plates with other crystallographic orientations.

The back surface 114 of the piezoelectric plate 110 is attached to a substrate 120 that provides mechanical support to the piezoelectric plate 110. The substrate 120 may be, for example, silicon, sapphire, quartz, or some other material. The piezoelectric plate 110 may be bonded to the substrate 120 using a wafer bonding process, or grown on the substrate 120, or attached to the substrate in some other manner. The piezoelectric plate may be attached directly to the substrate or may be attached to the substrate via one or more intermediate material layers.

The conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved. The interleaved fingers overlap for a distance AP, commonly referred to as the “aperture” of the IDT. The center-to-center distance L between the outermost fingers of the IDT 130 is the “length” of the IDT.

The first and second busbars 132, 134 serve as the terminals of the XBAR 100. A radio frequency or microwave signal applied between the two busbars 132, 134 of the IDT 130 excites an acoustic wave within the piezoelectric plate 110. As will be discussed in further detail, the excited acoustic wave is a bulk shear wave that propagates in the direction normal to the surface of the piezoelectric plate 110, which is also normal, or transverse, to the direction of the electric field created by the IDT fingers. Thus, the XBAR is considered a transversely-excited film bulk wave resonator.

A cavity 125 is formed in the substrate 120 such that the portion of the piezoelectric plate 110 containing the IDT 130 is suspended over the cavity 125 without contacting the substrate 120. “Cavity” has its conventional meaning of “an empty space within a solid body.” The cavity 125 may be a hole completely through the substrate 120 (as shown in Section A-A and Section B-B) or a recess in the substrate 120. The cavity 125 may be formed, for example, by selective etching of the substrate 120 before or after the piezoelectric plate 110 and the substrate 120 are attached. As shown in FIG. 1, the cavity 125 has a rectangular shape with an extent greater than the aperture AP and length L of the IDT 130. A cavity of an XBAR may have a different shape, such as a regular or irregular polygon. The cavity of an XBAR may have more or fewer than four sides, which may be straight or curved.

For ease of presentation in FIG. 1, the geometric pitch and width of the IDT fingers are greatly exaggerated with respect to the length (dimension L) and aperture (dimension AP) of the XBAR. A typical XBAR has more than ten parallel fingers in the IDT 110. An XBAR may have hundreds, possibly thousands, of parallel fingers in the IDT 110. Similarly, the thickness of the fingers in the cross-sectional views is greatly exaggerated.

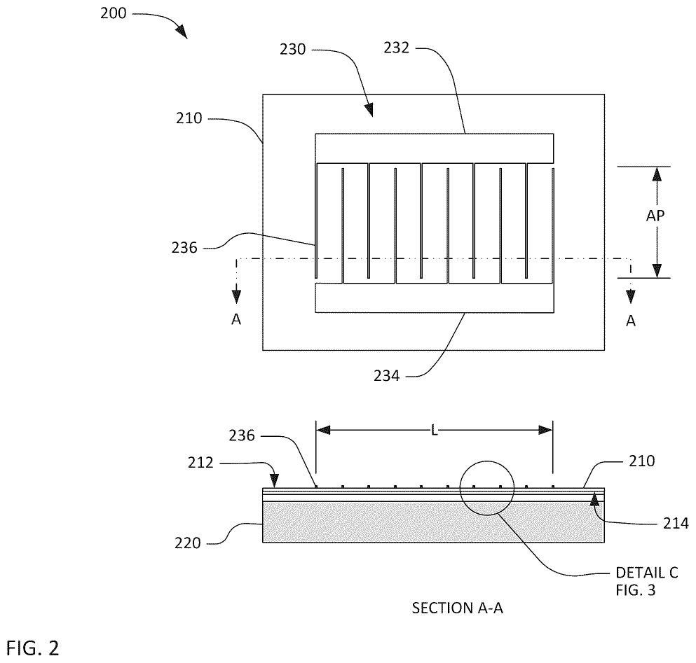

FIG. 2 shows a simplified schematic top view and an orthogonal cross-sectional view of a solidly-mounted transversely-excited film bulk acoustic resonator (SM XBAR) 200. SM XBAR resonators such as the resonator 200 may be used in a variety of RF filters including band-reject filters, band-pass filters, duplexers, and multiplexers. SM XBARs are particularly suited for use in filters for communications bands with frequencies above 3 GHz.

The SM XBAR 200 is made up of a thin film conductor pattern formed on a front surface 212 of a piezoelectric plate 210 having parallel front and back surfaces 212, 214, respectively. The piezoelectric plate is a thin single-crystal layer of a piezoelectric material such as lithium niobate, lithium tantalate, lanthanum gallium silicate, gallium nitride, or aluminum nitride. The piezoelectric plate is cut such that the orientation of the X, Y, and Z crystalline axes with respect to the front and back surfaces is known and consistent. In the examples presented in this patent, the piezoelectric plates are Z-cut, which is to say the Z axis is normal to the surfaces of the plate. However, SM XBARs may be fabricated on piezoelectric plates with other crystallographic orientations.

The back surface 214 of the piezoelectric plate 210 is attached to, and mechanically supported by, a substrate 220. The substrate 220 may be, for example, silicon, sapphire, quartz, or some other material. As will be described subsequently, the piezoelectric plate 210 may be attached to the substrate 220 via a plurality of intermediate material layers.

The conductor pattern of the SM XBAR 200 includes an interdigital transducer (IDT) 230. The IDT 230 includes a first plurality of parallel fingers, such as finger 236, extending from a first busbar 232 and a second plurality of fingers extending from a second busbar 234. The first and second pluralities of parallel fingers are interleaved. The interleaved fingers overlap for a distance AP, commonly referred to as the “aperture” of the IDT. The center-to-center distance L between the outermost fingers of the IDT 230 is the “length” of the IDT. Each finger of the first and second pluralities of fingers may be parallel to the X axis of the piezoelectric plate 210.

The first and second busbars 232, 234 serve as the terminals of the SM XBAR 200. A radio frequency or microwave signal applied between the two busbars 232, 234 of the IDT 230 excites an acoustic wave within the piezoelectric plate 210. As will be discussed in further detail, the excited acoustic wave is a bulk shear wave that propagates in the direction normal to the surface of the piezoelectric plate 210, which is also normal, or transverse, to the direction of the electric field created by the IDT fingers. Thus, the SM XBAR is considered a transversely-excited film bulk wave resonator.

For ease of presentation in FIG. 2, the geometric pitch and width of the IDT fingers are greatly exaggerated with respect to the length (dimension L) and aperture (dimension AP) of the SM XBAR. A typical SM XBAR has more than ten parallel fingers in the IDT 210. An SM XBAR may have hundreds, possibly thousands, of parallel fingers in the IDT 210. Similarly, the thickness of the fingers in the cross-sectional views is greatly exaggerated.

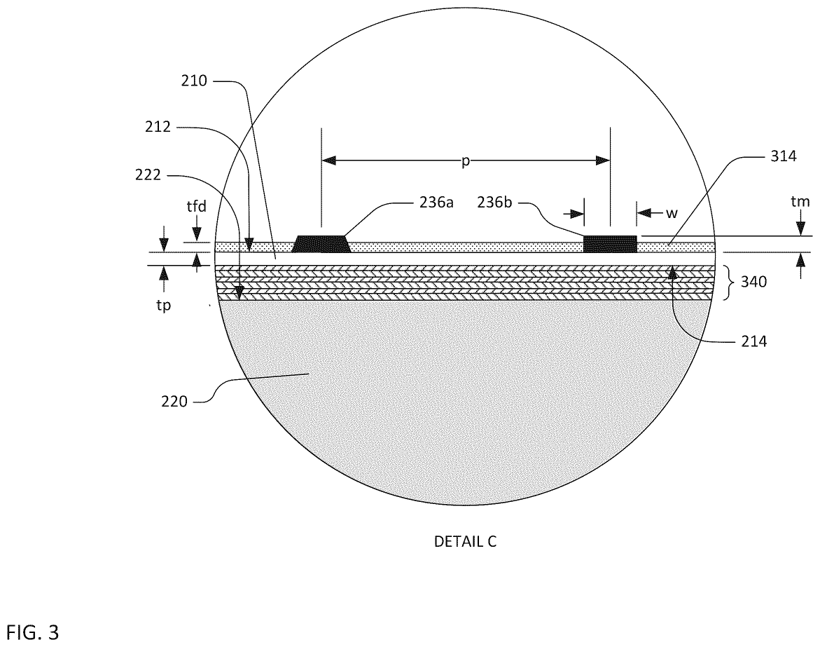

FIG. 3 shows a detailed schematic cross-sectional view of the SM XBAR 200. The piezoelectric plate 210 is a single-crystal layer of piezoelectrical material having a thickness tp. The value of tp is approximately one-half of the bulk acoustic wavelength at the resonance frequency. tp may be, for example, 50 nm to 200 nm for applications at frequencies from about 9 GHz to 30 GHz. When used in filters for communications devices operating in one of the 27 GHz bands, the thickness tp may be, for example, 50 nm to 90 nm.

A front-side dielectric layer 314 may optionally be formed on the front surface 212 of the piezoelectric plate 210. The front-side dielectric layer 314 has a thickness tfd. The front-side dielectric layer 314 may be formed between the IDT fingers 236a, 236b. Although not shown in FIG. 2, the front side dielectric layer 314 may also be deposited over the IDT fingers 236a, 236b. The front-side dielectric layer 314 may be a non-piezoelectric dielectric material, such as silicon dioxide or silicon nitride. tfd may be, for example, 0 to not more than 30% of the thickness tp of the piezoelectric plate 210.

The IDT fingers 236a, 236b may be aluminum or a substantially aluminum alloy, copper or a substantially copper alloy, beryllium, gold, or some other conductive material. Thin (relative to the total thickness of the conductors) layers of other metals, such as chromium or titanium, may be formed under and/or over the fingers to improve adhesion between the fingers and the piezoelectric plate 210 and/or to passivate or encapsulate the fingers. The busbars (232, 234 in FIG. 2) of the IDT may be made of the same or different materials as the fingers. The cross-sectional shape of the IDT fingers may be trapezoidal (e.g. IDT finger 236a) or rectangular (e.g. IDT finger 236b), or some other shape (not shown).

Dimension p is the center-to-center spacing or “pitch” of the IDT fingers, which may be referred to as the pitch of the IDT and/or the pitch of the SM XBAR. Dimension w is the width or “mark” of the IDT fingers. The IDT of an SM XBAR differs substantially from the IDTs used in surface acoustic wave (SAW) resonators. In a SAW resonator, the pitch of the IDT is one-half of the acoustic wavelength at the resonance frequency. Additionally, the ratio of the finger width to the pitch of a SAW resonator IDT is typically close to 0.5 (i.e. the mark or finger width w is about one-fourth of the acoustic wavelength at resonance). In an SM XBAR, the width w of the IDT fingers is typically 0.2 to 0.3 times the pitch p of the IDT.

The pitch p of the IDT may be 2 to 20 times the thickness tp of the piezoelectric plate 210. When used in filters for communications devices operating in one of the 27 GHz communications bands, the pitch p is typically 8 to 15 times the thickness tp of the piezoelectric plate 210. The thickness tm of the IDT fingers 236a, 236b is typically 0.8 to 1.5 times the thickness tp of the piezoelectric plate 210. The thickness of the busbars (232, 234 in FIG. 2) of the IDT may be the same as, or greater than, the thickness tm of the IDT fingers.

An acoustic Bragg reflector 340 is sandwiched between a surface 222 of the substrate 220 and the back surface 214 of the piezoelectric plate 110. The term “sandwiched” means the acoustic Bragg reflector 340 is both disposed between and physically connected to the surface 222 of the substrate 220 and the back surface 214 of the piezoelectric plate 210. In some circumstances, thin layers of additional materials may be disposed between the acoustic Bragg reflector 340 and the surface 222 of the substrate 220 and/or between the Bragg reflector 340 and the back surface 214 of the piezoelectric plate 210. Such additional material layers may be present, for example, to facilitate bonding the piezoelectric plate 210, the acoustic Bragg reflector 340, and the substrate 220.

The acoustic Bragg reflector 340 includes multiple layers that alternate between materials having high acoustic impedance and materials have low acoustic impedance. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. Each of the layers has a thickness equal to, or about, one-fourth of the acoustic wavelength at or near a resonance frequency of the SM XBAR 200. All of the high acoustic impedance layers of the acoustic Bragg reflector 340 are not necessarily the same material, and all of the low acoustic impedance layers are not necessarily the same material.

Dielectric materials having comparatively low acoustic impedance include silicon dioxide, silicon oxycarbide, and certain plastics such as cross-linked polyphenylene polymers. Materials having comparatively high acoustic impedance include silicon nitride, aluminum nitride, silicon carbide, diamond, diamond-like carbon (DLC), cubic boron nitride (c-BN), and hafnium oxide. Aluminum has comparatively low acoustic impedance and other metals such as molybdenum, tungsten, gold, and platinum have comparatively high acoustic impedance. However, the presence of metal layers in the acoustic Bragg reflector 340 will distort the electric field generated by the IDT fingers and substantially reduce the electromechanical coupling of the SM XBAR. Thus, all of the layers of the acoustic Bragg reflector 340 may be dielectric materials.

In the example of FIG. 2, the acoustic Bragg reflector 340 has a total of six layers or three pairs of layers. An acoustic Bragg reflector may have more than, or less than, six layers.

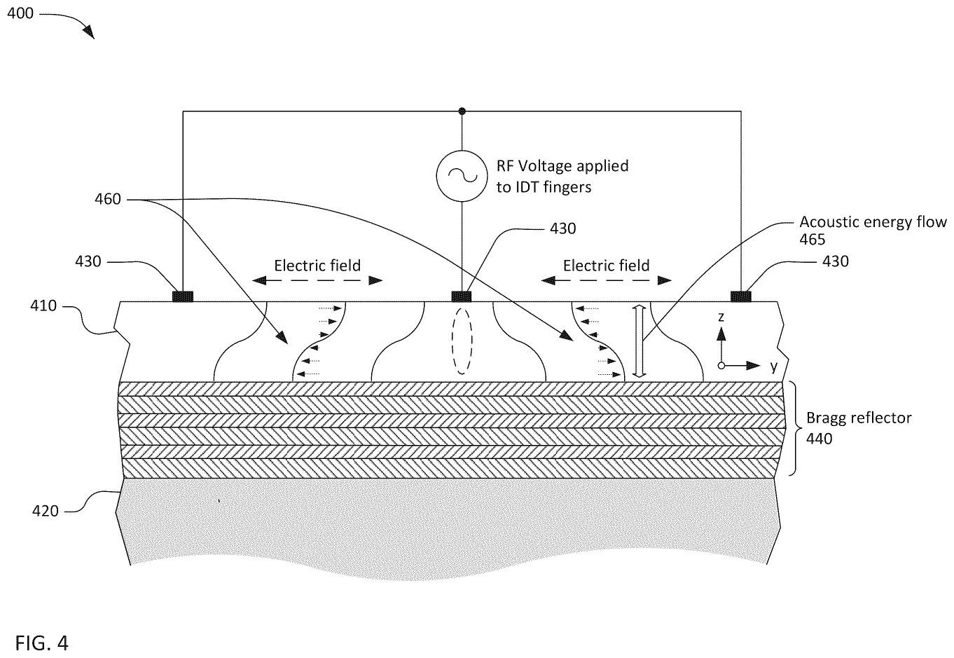

FIG. 4 is a graphical illustration of the primary acoustic mode in a SM XBAR 400. FIG. 4 shows a small portion of the SM XBAR 400 including a piezoelectric plate 410 and three interleaved IDT fingers 430. The piezoelectric plate 410 may be single-crystal lithium niobate cut such that the z-axis is normal to the surfaces of the plate. The IDT fingers may be oriented parallel to the x-axis of the plate such that the y-axis is normal to the fingers.

An RF voltage applied to the interleaved fingers 430 creates a time-varying electric field between the fingers. In the regions between the IDT fingers 430, the direction of the electric field is predominantly lateral, or parallel to the surface of the piezoelectric plate 410, and orthogonal to the length of the IDT fingers, as indicated by the dashed arrows labeled “electric field”. Due to the high dielectric constant of the piezoelectric plate, the electric field is highly concentrated in the plate relative to the air. The lateral electric field excites acoustic waves in the piezoelectric plate 410. In an XBAR, the piezoelectric plate and the IDT are configured such that the lateral electric field causes shear deformation, and thus strongly excites shear-mode acoustic waves, in the piezoelectric plate 410. In this context, “shear deformation” is defined as deformation in which parallel planes in a material remain parallel and maintain a constant distance while translating relative to each other. “Shear acoustic waves” are defined as acoustic waves in a medium that result in shear deformation of the medium. The shear deformations in the piezoelectric plate 410 are represented by the curves 460, with the adjacent small arrows providing a schematic indication of the direction and magnitude of atomic motion. The degree of atomic motion, as well as the thickness of the piezoelectric plate 410, have been greatly exaggerated for ease of visualization. While the atomic motions are predominantly lateral (i.e. horizontal as shown in FIG. 4), the direction of acoustic energy flow of the primary shear acoustic mode is substantially orthogonal to the surface of the piezoelectric plate, as indicated by the arrow 465. Other secondary or spurious acoustic modes may also be excited in addition to the primary shear acoustic mode.

An acoustic Bragg reflector 440 is sandwiched between the piezoelectric plate 410 and a substrate 420. The acoustic Bragg reflector 440 reflects the acoustic waves of the primary acoustic mode to keep the acoustic energy (arrow 465) predominantly confined to the piezoelectric plate 410. The acoustic Bragg reflector 440 for an XBAR consists of alternating layers of materials having relatively high and relatively low acoustic impedance, with each layer having a thickness of about one-quarter of the wavelength of the shear acoustic waves (arrow 465) at resonance frequency of the XBAR 400. In the example of FIG. 4, the acoustic Bragg reflector 440 has a total of six layers. An acoustic Bragg reflector may have more than, or less than, six layers.

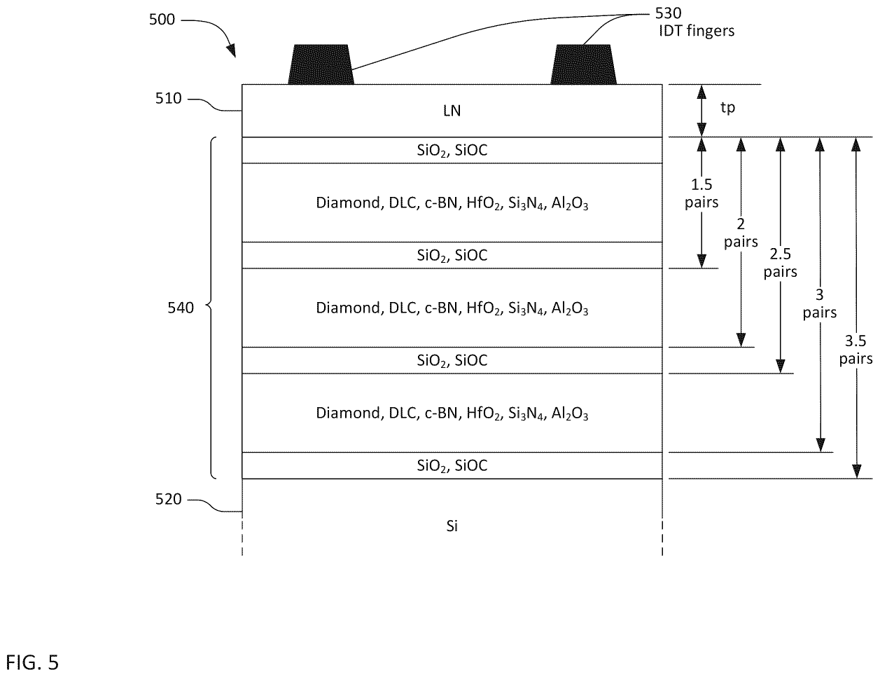

FIG. 5 is a schematic cross-sectional view of a SM XBAR 500 with an acoustic Bragg reflector 540 comprising alternating low acoustic impedance and high acoustic impedance dielectric layers. The low acoustic impedance layers may before example, SiO₂ or carbon-containing silicon oxide (SiOC). The high acoustic impedance layers may be, for example, diamond, diamond-like carbon (DLC), cubic boron nitride (c-BN), HfO₂, Si₃N₄, or Al₂O₃. The acoustic Bragg reflector 540 is sandwiched between a piezoelectric plate 510 and a substrate 520. The piezoelectric plate may be lithium niobate (LN) or lithium tantalate or some other material. The piezoelectric plate may be Z-cut (i.e. Z axis perpendicular to the surfaces), rotated Z-cut or rotated Y-cut LN. The substrate 520 may be silicon or some other material. The acoustic Bragg reflector 540 has a total of seven layers, or 3.5 pairs of layers.

The Q-factor of an acoustic resonator is defined as the energy stored in the resonator divided by the energy lost during one radian of the RF input to the resonator. The energy lost in the resonator has various components including resistive losses in the conductors, acoustic or viscous losses in the conductors and piezoelectric plate, energy lost to spurious resonant modes, and, for SM-XBARs, energy lost by leakage through the acoustic Bragg reflector into the substrate. Individual Q-factors may be defined for each of the loss components such that

1/Q=1/Q_{BR}+1/Q_{R}+1/Q_{A}+ (1)

where Q is the overall Q-factor of the resonator and Q_{BR}, Q_{R}, and Q_{A} are the Q-factors for leakage through the Bragg grating, resistive losses, and acoustic losses, respectively. Q_{BR} is equivalent to the Q-factor of an otherwise ideal resonator with no losses other than leakage through the acoustic Bragg reflector. Many of these Q-factors are dependent on frequency.

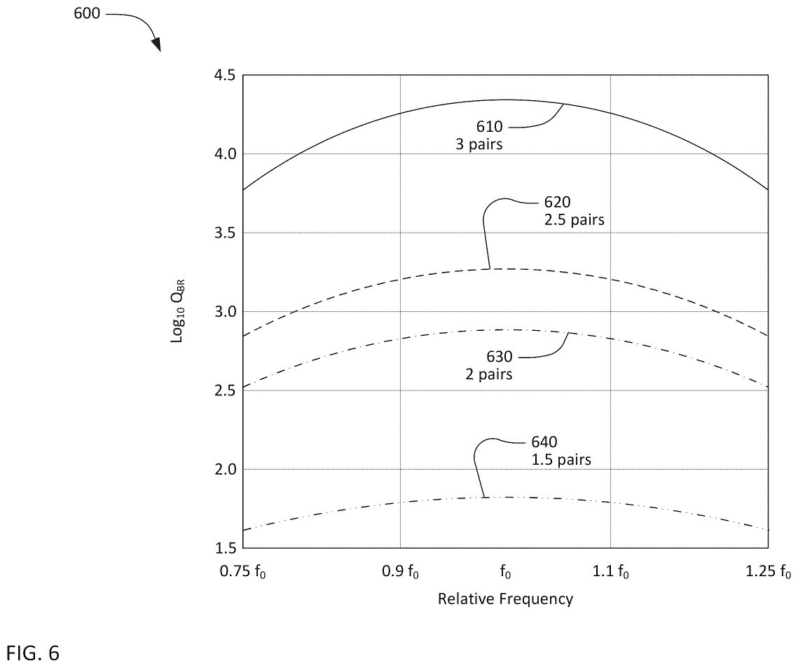

FIG. 6 is a chart showing the relationship between Q_{BR} and the number of layers in an acoustic Bragg reflector composed of alternating SiO₂ and diamond layers. Specifically, FIG. 6 is graph of Log₁₀ Q_{BR} versus relative frequency with number of layers as a parameter. f₀ is the center frequency of the Bragg reflector, which is to say the frequency at which the effective thickness of the layers of the acoustic Bragg reflector are ¼ wavelength.

The solid line 610 is a plot of Q_{BR} for SM XBARs with an acoustic Bragg reflector with 3 pairs of SiO₂/Diamond layers (6 total layers). The dashed line 620 is a plot of Q_{BR} for SM XBARs with an acoustic Bragg reflector with 2.5 pairs of SiO₂/Diamond layers (5 total layers). The dot-dash line 630 is a plot of Q_{BR} for SM XBARs with an acoustic Bragg reflector with 2 pairs of SiO₂/Diamond layers (4 total layers). The dot-dot-dash line 640 is a plot of Q_{BR} for SM XBARs with an acoustic Bragg reflector with 1.5 pairs of SiO₂/Diamond layers (3 total layers). An acoustic Bragg reflector with 2.5 pairs of alternating SiO₂ and diamond layers may be sufficient for most XBAR filters. Acoustic Bragg reflectors using material other than SiO₂ and diamond may require more than 2.5 pairs of layers. The data shown in FIG. 6 results from simulation using a finite element method.

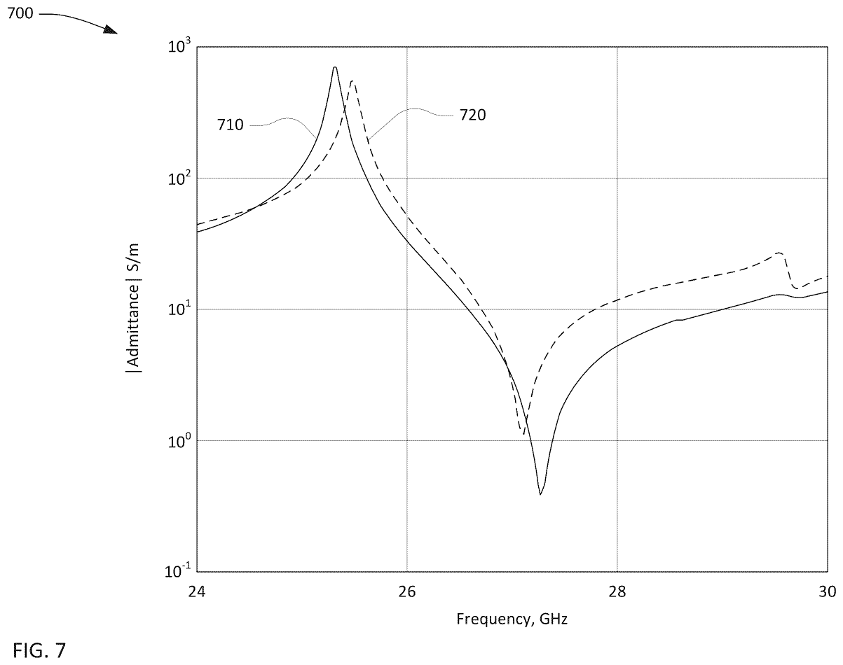

FIG. 7 is a chart 700 of the normalized magnitude of the admittance (on a logarithmic scale) versus frequency for two representative SM XBARs having structures similar to the SM XBAR 500 of FIG. 5. The data is FIG. 7 is based on simulation of the SM XBAR structures using a finite element method.

Specifically, the solid curve 710 is a plot of the magnitude of admittance of an SM XBAR including a Z-cut LN piezoelectric plate with a thickness tp of 71 nm. The pitch, width, and thickness of the aluminum IDT fingers are 1 μm, 250 nm, and 80 nm, respectively. The acoustic Bragg reflector includes three pairs of alternating SiO₂ and DLC layers with thicknesses of 40 nm and 136 nm, respectively. There is no front side dielectric layer. The resonance frequency Fr is 25.3 GHZ, the anti-resonance frequency Far is 27.3 GHZ, and the R-aR bandwidth is 7.7%. R-aR bandwidth is defined as (Fr-Far)/Fr.

The dashed curve 720 is a plot of the magnitude of admittance of an SM XBAR with the same construction as the previous example except the Bragg reflector is alternating SiO₂ and HfO₂ layers. The resonance frequency Fr is 25.5 GHZ, the anti-resonance frequency Far is 27.1 GHZ, and the R-aR bandwidth is 6.2%.

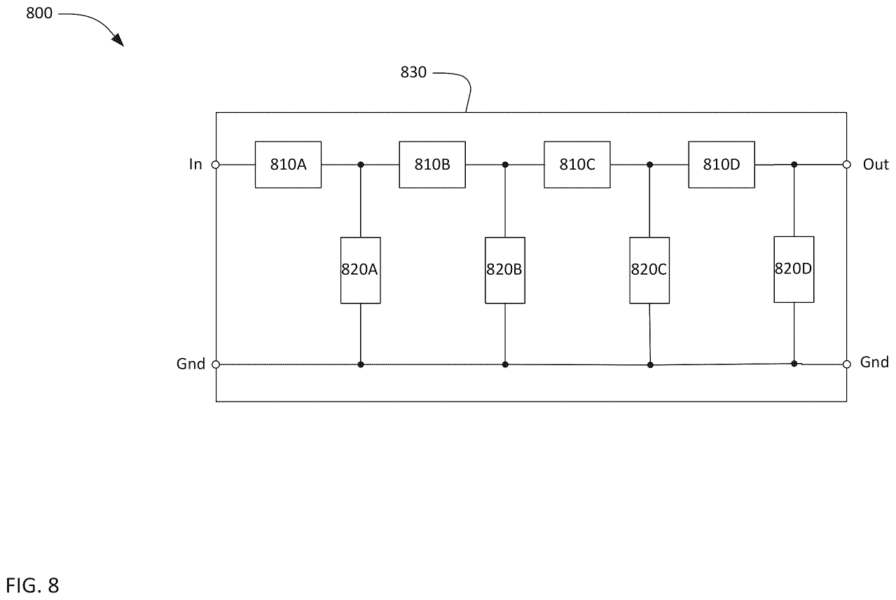

FIG. 8 is a schematic circuit diagram for a high frequency band-pass filter 800 using SM XBARs. The filter 800 has a conventional ladder filter architecture including four series resonators 810A, 810B, 810C, 810D and four shunt resonators 820A, 820B, 820C, 820D. The four series resonators 810A, 810B, 810C, and 810D are connected in series between a first port and a second port. In FIG. 8, the first and second ports are labeled “In” and “Out”, respectively. However, the filter 800 is reversible in that either port and serve as the input or output of the filter. The four shunt resonators 820A, 820B, 820C, 820D are connected from nodes between the series resonators to ground. All the shunt resonators and series resonators are SM XBARs.

The filter 800 may include a substrate having a surface, a single-crystal piezoelectric plate having parallel front and back surfaces, and an acoustic Bragg reflector sandwiched between the surface of the substrate and the back surface of the single-crystal piezoelectric plate. The substrate, acoustic Bragg reflector, and piezoelectric plate are represented by the rectangle 830 in FIG. 8. A conductor pattern formed on the front surface of the single-crystal piezoelectric plate includes interdigital transducers (IDTs) for each of the four series resonators 810A, 8110B, 810C, 810D and four shunt resonators 820A, 820B, 820C, 820D. All of the IDTs are configured to excite shear acoustic waves in the single-crystal piezoelectric plate in response to respective radio frequency signals applied to each IDT.

In a ladder filter, such as the filter 800, the resonance frequencies of shunt resonators are typically lower than the resonance frequencies of series resonators. The resonance frequency of an SM XBAR resonator is primarily determined by the thickness of the material stack above the acoustic Bragg reflector, which is to say the combined thickness of the piezoelectric plate and top side dielectric layer(s) if present. The resonance frequency of an SM XBAR is slightly dependent on IDT pitch and, to an even smaller extent, IDT finger width. IDT pitch and finger width also impacts other filter parameters including impedance and power handling capability. For 27 GHz communications band filter applications, it may not be practical to provide the required difference between the resonance frequencies of shunt and series resonators using only differences in IDT pitch and finger width. The required difference between the resonance frequencies of shunt and series resonators can be achieved by using different material stack thicknesses for series and shunt resonator.

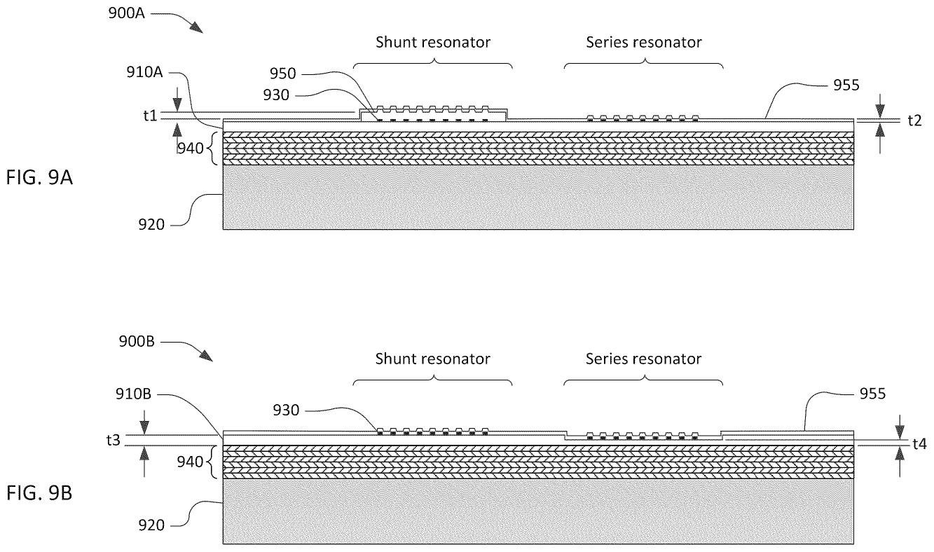

FIG. 9A is a schematic cross-sectional view though a shunt resonator and a series resonator of a filter 900A that uses dielectric thickness to separate the frequencies of shunt and series resonators. An acoustic Bragg reflector 940 is sandwiched between a piezoelectric plate 910A and a substrate 920. The piezoelectric plate 910A has a uniform thickness. Interleaved IDT fingers, such as finger 930, are formed on the piezoelectric plate 910A. A first dielectric layer 950, having a thickness t1, is deposited over the shunt resonator. A second dielectric layer 955, having a thickness t2, is deposited over both the shunt and series resonator. Alternatively, a single dielectric layer having thickness t1+t2 may be deposited over both the shunt and series resonators. The dielectric layer over the series resonator may then be thinned to thickness t2 using a masked dry etching process. In either case, the difference between the overall thickness of the dielectric layers (t1+t2) over the shunt resonator and the thickness t2 of the dielectric layer over the series resonator defines a frequency offset between the series and shunt resonators.

The second dielectric layer 955 may also serve to seal and passivate the surface of the filter 900A. The second dielectric layer may be the same material as the first dielectric layer or a different material. The second dielectric layer may be a laminate of two or more sub-layers of different materials. Alternatively, an additional dielectric passivation layer (not shown in FIG. 9A) may be formed over the surface of the filter 900A. Further, as will be described subsequently, the thickness of the final dielectric layer (i.e. either the second dielectric layer 955 or an additional dielectric layer) may be locally adjusted to fine-tune the frequency of the filter 900A. The final dielectric layer can be referred to as the “passivation and tuning layer”.

FIG. 9B is a schematic cross-sectional view though a shunt resonator and a series resonator of a filter 900B that uses piezoelectric plate thickness to separate the frequencies of shunt and series resonators. An acoustic Bragg reflector 940 is sandwiched between a piezoelectric plate 910B and a substrate 920. Interleaved IDT fingers, such as finger 930, are formed on the diaphragms. The diaphragm of the shunt resonator has a thickness t3. The piezoelectric plate 910B is selectively thinned (for example, as described in Patent No. U.S. Pat. No. 11,201,601) such that the diaphragm of the series resonator has a thickness t4, which is less than t3. The difference between t3 and t4 defines a frequency offset between the series and shunt resonators. A passivation and tuning layer 955 may be deposited over both the shunt and series resonators.

A filter using SM XBARS is not limited to either two dielectric thicknesses as shown in FIG. 9A or two piezoelectric plate thicknesses as shown in FIG. 9B. Filters may use three or more dielectric thicknesses, three or more piezoelectric plate thicknesses, or a combination of multiple dielectric thicknesses and multiple piezoelectric plate thicknesses.

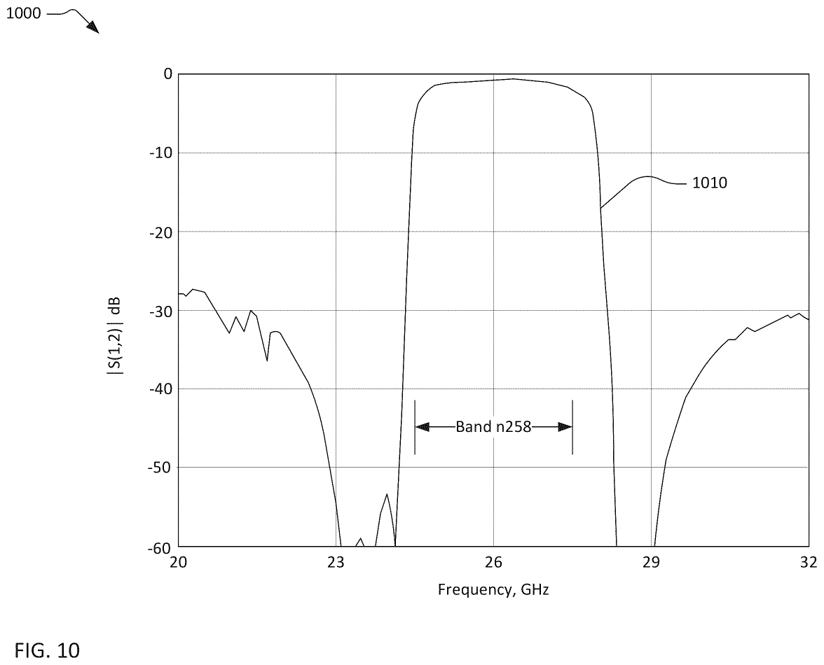

FIG. 10 is a chart 1000 illustrating the application of SM XBARS in bandpass filters for K band communications devices. The solid curve 1010 is a plot of the magnitude of the input-output transfer function S(1,2) of an exemplary filter for 5G NR band n258. This filter includes eight SM XBARs connected in a ladder filter circuit as shown in FIG. 8 with shunt impedance matching inductors (not shown in FIG. 8) across the input and output ports. The data results from simulation of the filter using a finite element technique. All eight XBARs are on a common silicon substrate with a common acoustic Bragg reflector with 4 pairs of alternating SiO₂ and DLC layers. The piezoelectric plate is Z-cut LN with a thickness of 68 nm for series resonators and 79 nm for three of the four shunt resonators and 81.5 nm for the fourth shunt resonator. The IDT electrode are aluminum 90 nm thick. The pitch of the IDTs ranges from 0.775 μm to 1.1 μm. The IDT finger width to pitch ratio is 0.235 or 0.25 for all SM XBARs. The IDT pitch to piezoelectric plate thickness ratio ranges between 9.8 and 16. Resonance frequencies of shunt resonators are between 23.2 GHz and 24.2 GHz, which are below the lower edge of the filter passband. Resonance frequencies of series resonators are between 26.3 and 26.7 GHZ, which are within the filter passband.

### Description of Methods

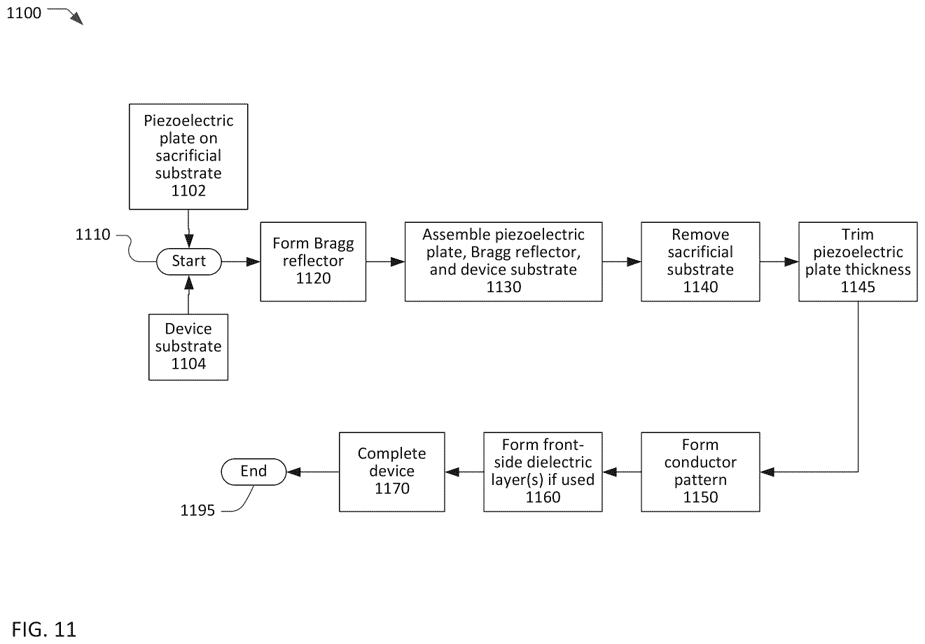

FIG. 11 is a simplified flow chart of a method 1100 for making a SM XBAR or a filter incorporating SM XBARs. The method 1100 starts at 1110 with a piezoelectric film disposed on a sacrificial substrate 1102 and a device substrate 1104. The method 1110 ends at 1195 with a completed SM XBAR or filter. The flow chart of FIG. 11 includes only major process steps. Various conventional process steps (e.g. surface preparation, cleaning, inspection, baking, annealing, monitoring, testing, etc.) may be performed before, between, after, and during the steps shown in FIG. 11.

Thin plates of single-crystal piezoelectric materials bonded to a non-piezoelectric substrate are commercially available. At the time of this application, both lithium niobate and lithium tantalate plates are available bonded to various substrates including silicon, quartz, and fused silica. Thin plates of other piezoelectric materials may be available now or in the future. The thickness of the piezoelectric plate may be between 50 nm and 200 nm. The thickness of the piezoelectric plate at 1102 may be equal to a desired final thickness. The thickness of the piezoelectric plate at 1102 may be greater than the final thickness and may be trimmed to the final thickness at a later step in the process 1100. When the substrate is silicon, a layer of SiO₂ may be disposed between the piezoelectric plate and the substrate. The piezoelectric plate 1102 may be, for example, z-cut lithium niobate bonded to a silicon wafer with an intervening SiO₂ layer. The device substrate 1104 may be silicon (as used in the previous examples) fused silica, quartz, or some other material.

At 1120 an acoustic Bragg reflector is formed by depositing alternating layers of materials having low and high acoustic impedance as previously described. Each of the layers has a thickness equal to or about one-fourth of the acoustic wavelength. The total number of layers in the acoustic Bragg reflector may typically be from five to eight.

At 1120, all of the layers of the acoustic Bragg reflector may be deposited on either the surface of the piezoelectric plate on the sacrificial substrate 1102 or a surface of the device substrate 1104. Alternatively, some of the layers of the acoustic Bragg reflector may be deposited on the surface of the piezoelectric plate on the sacrificial substrate 1102 and the remaining layers of the acoustic Bragg reflector may be deposited on a surface of the device substrate 1104.

At 1130, the piezoelectric plate on the sacrificial substrate 1102 and the device substrate 1104 may be bonded such that the layers of the acoustic Bragg reflector are sandwiched between the piezoelectric plate and the device substrate. The piezoelectric plate on the sacrificial substrate 1102 and the device substrate 1104 may be bonded using a wafer bonding process such as direct bonding, surface-activated or plasma-activated bonding, electrostatic bonding, or some other bonding technique. Note that, when one or more layers of the acoustic Bragg reflector are deposited on both the piezoelectric plate and the device substrate, the bonding will occur between or within layers of the acoustic Bragg reflector.

After the piezoelectric plate on the sacrificial substrate 1102 and the device substrate 1104 are bonded, the sacrificial substrate, and any intervening layers, are removed at 1140 to expose the surface of the piezoelectric plate (the surface that previously faced the sacrificial substrate). The sacrificial substrate may be removed, for example, by material-dependent wet or dry etching or some other process.

A variation of the method from 1110 to 1140 starts with a single-crystal piezoelectric wafer at 1102 instead of a thin piezoelectric plate on a sacrificial substrate of a different material. Ions are implanted to a controlled depth beneath a surface of the piezoelectric wafer (not shown in FIG. 11). The portion of the wafer from the surface to the depth of the ion implantation is (or will become) the thin piezoelectric plate and the balance of the wafer is the sacrificial substrate. The acoustic Bragg reflector is formed at 1120 as previously described and the piezoelectric wafer and device substrate are bonded at 1130 such that the acoustic Bragg reflector is disposed between the ion-implanted surface of the piezoelectric wafer 1102 and the device substrate 1104. At 1140, the piezoelectric wafer may be split at the plane of the implanted ions (for example, using thermal shock), leaving a thin plate of piezoelectric material exposed and bonded to the acoustic Bragg reflector. The thickness of the thin plate piezoelectric material is determined by the energy (and thus depth) of the implanted ions. The process of ion implantation and subsequent separation of a thin plate is commonly referred to as “ion slicing”. The thickness of the piezoelectric plate after ion slicing may be equal to or greater than the desired final thickness.

At 1145, the thickness of the piezoelectric plate may be adjusted or trimmed to a desired final thickness. Trimming may include, for example, polishing or chemo-mechanical polishing the surface of the piezoelectric plate. Trimming may include globally or selectively removing material from the surface of the piezoelectric plate using an ion mill or other material removal tool. Trimming may include measuring a thickness profile of the piezoelectric plate and then removing material by polishing, ion milling, or some other technique based on the thickness profile to improve the thickness uniformity of the piezoelectric plate. Trimming may include applying a mask and removing material from selected regions of the piezoelectric plate (e.g. regions that will become series resonators). When fabricating filters for 27 GHz communications bands, the final thickness of the piezoelectric plate may be, for example, 50 nm to 90 nm.

After the thickness of the piezoelectric plate is trimmed at 1145, a conductor pattern, including IDTs of each SM XBAR, is formed at 1150 by depositing and patterning one or more conductor layers on the trimmed surface of the piezoelectric plate. The conductor pattern may be, for example, aluminum, an aluminum alloy, copper, a copper alloy, or some other conductive metal. Optionally, one or more layers of other materials may be disposed below (i.e. between the conductor layer and the piezoelectric plate) and/or on top of the conductor layer. For example, a thin film of titanium, chrome, or other metal may be used to improve the adhesion between the conductor layer and the piezoelectric plate. When the conductor layer is substantially aluminum, the IDT finger thickness may be from 0.8 to 1.5 times the final thickness of the piezoelectric plate. A conduction enhancement layer of gold, aluminum, copper or other higher conductivity metal may be formed over portions of the conductor pattern (for example the IDT bus bars and interconnections between the IDTs).

The conductor pattern may be formed at 1150 by depositing the conductor layer and, optionally, one or more other metal layers in sequence over the surface of the piezoelectric plate. The excess metal may then be removed by etching through patterned photoresist. The conductor layer can be etched, for example, by plasma etching, reactive ion etching, wet chemical etching, and other etching techniques.

Alternatively, the conductor pattern may be formed at 1150 using a lift-off process. Photoresist may be deposited over the piezoelectric plate, and patterned to define the conductor pattern. The conductor layer and, optionally, one or more other layers may be deposited in sequence over the surface of the piezoelectric plate. The photoresist may then be removed, which removes the excess material, leaving the conductor pattern.

At 1160, one or more optional front-side dielectric layers may be formed by depositing one or more layers of dielectric material on the front side of the piezoelectric plate. The one or more dielectric layers may be deposited using a conventional deposition technique such as sputtering, evaporation, or chemical vapor deposition. The one or more dielectric layers may be deposited over the entire surface of the piezoelectric plate, including on top of the conductor pattern. Alternatively, one or more lithography processes (using photomasks) may be used to limit the deposition of the dielectric layers to selected areas of the piezoelectric plate, such as only between the interleaved fingers of the IDTs. Masks may also be used to allow deposition of different thicknesses of dielectric materials on different portions of the piezoelectric plate. For example, a first dielectric layer having a first thickness t1 may be deposited over the IDTs of one or more shunt resonators. A second dielectric layer having a second thickness t2, where t2 is equal to or greater than zero and less than t1, may be deposited over the IDTs of series resonators.

After the conductor pattern and optional front-side dielectric layer are formed at 1150 and 1160, the filter device may be completed at 1170. Actions that may occur at 1170 including depositing and patterning additional metal layers to form conductors other than the IDT conductor pattern; depositing an encapsulation/passivation layer such as SiO₂ or Si₃O₄ over all or a portion of the device; forming bonding pads or solder bumps or other means for making connection between the device and external circuitry; excising individual devices from a wafer containing multiple devices; other packaging steps; and testing. Another action that may occur at 1170 is to tune the resonant frequencies of the resonators within the device by adding or removing metal or dielectric material from the front side of the device. After the filter device is completed, the process ends at 1195.

### Closing Comments

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. A radio frequency filter, comprising:
a substrate;
a piezoelectric layer;
a conductor pattern comprising a plurality of interdigital transducers (IDTs) on the piezoelectric layer; and
an acoustic Bragg reflector between the substrate and the piezoelectric layer,
wherein the plurality of IDTs comprises a first IDT of first acoustic resonator and a second IDT of a second acoustic resonator, and
wherein a first thickness of the piezoelectric layer under the first IDT is greater than a second thickness of piezoelectric layer under the second IDT.

2. The radio frequency filter of claim 1, wherein each of the plurality of IDTs and the piezoelectric layer are configured such that a radio frequency signal applied to each of the plurality of IDTs primarily excites a shear acoustic mode within the piezoelectric layer, wherein the primarily excited shear acoustic mode has an electric field having a direction that is predominantly lateral, and the propagation is substantially normal to the direction of the electric field and substantially normal to a surface of the piezoelectric layer.

3. The radio frequency filter of claim 1, wherein each IDT of the plurality of IDTs comprises interleaved fingers on the piezoelectric layer, and at least a portion of the interleaved fingers have a width that is greater than or equal to 0.2 times a pitch of the respective IDT and less than or equal to 0.3 times the pitch of the respective IDT.

4. The radio frequency filter of claim 1, wherein the first thickness is greater than 0.05 times a pitch of the first IDT, wherein pitch is a center-to-center distance between two adjacent fingers of the first IDT extending from different busbars.

5. The radio frequency filter of claim 1, wherein the second thickness is greater than 0.05 times a pitch of the second IDT, and wherein pitch is a center-to-center distance between two adjacent fingers of the second IDT extending from different busbars.

6. The radio frequency filter of claim 2, wherein the acoustic Bragg reflector is configured to reflect the primarily excited shear acoustic mode over a frequency range including a resonance frequency and an anti-resonance frequency of the radio frequency filter.

7. The radio frequency filter of claim 1, wherein the pitch of the interleaved fingers of the first IDT is greater than or equal to 8 times the first thickness of the piezoelectric layer and less than or equal to 15 times the first thickness of the piezoelectric layer.

8. The radio frequency filter of claim 1, wherein either the first thickness, the second thickness or both the first and second thickness is greater than or equal to 50 nanometers and less than 200 nanometers.

9. The radio frequency filter of claim 1, wherein the interleaved fingers of the first IDT are substantially aluminum and an IDT finger thickness, of at least one of the plurality of IDTs, is greater than or equal to 0.8 times the first thickness of the piezoelectric layer and less than or equal to 1.5 times the first thickness of the piezoelectric layer.

10. A filter device comprising:
a substrate;
a piezoelectric layer;
a conductor pattern comprising a plurality of interdigital transducers (IDTs) on the piezoelectric layer; and
an acoustic Bragg reflector between the substrate and the piezoelectric layer,
wherein the plurality of IDTs comprises a first IDT of first acoustic resonator and a second IDT of a second acoustic resonator,
wherein a first thickness of the piezoelectric layer under the first IDT is greater than a second thickness of piezoelectric layer under the second IDT, and
wherein the first IDT is a shunt resonator and the second IDT is a series resonator.

11. The filter device of claim 10, wherein each of the plurality of IDTs and the piezoelectric layer are configured such that a radio frequency signal applied to each of the plurality of IDTs primarily excites a shear acoustic mode within the piezoelectric layer, wherein the primarily excited shear acoustic mode has an electric field having a direction which is predominantly lateral, and the propagation is substantially normal to the direction of the electric field and substantially normal to a surface of the piezoelectric layer.

12. The filter device of claim 10, wherein each of the plurality of IDTs comprises interleaved fingers on the piezoelectric layer, and at least a portion of the interleaved fingers have a width that is greater than or equal to 0.2 times a pitch of the respective IDT and less than or equal to 0.3 times the pitch of the respective IDT.

13. The filter device of claim 10, wherein the first thickness is greater than 0.05 times a pitch of the first IDT, wherein pitch is a center-to-center distance between two adjacent fingers of the first IDT extending from different busbars.

14. The filter device of claim 10, wherein the second thickness is greater than 0.05 times a pitch of the second IDT, wherein pitch is a center-to-center distance between two adjacent fingers of the second IDT extending from different busbars.

15. The filter device of claim 11, wherein the acoustic Bragg reflector is configured to reflect the primarily excited shear acoustic mode over a frequency range including a resonance frequency and an anti-resonance frequency of the filter device.

16. The filter device of claim 10, wherein the pitch of the interleaved fingers of the first IDT is greater than or equal to 8 times the first thickness of the piezoelectric layer and less than or equal to 15 times the first thickness of the piezoelectric layer.

17. The filter device of claim 10, wherein either the first thickness, the second thickness or both the first and second thickness is greater than or equal to 50 nanometers and less than 200 nanometers.

18. The filter device of claim 10, wherein the interleaved fingers of the first IDT are substantially aluminum and an IDT finger thickness, of at least one of the plurality of IDTs, is greater than or equal to 0.8 times the first thickness of the piezoelectric layer and less than or equal to 1.5 times the first thickness of the piezoelectric layer.

19. A method of manufacturing a filter device, the method comprising:
attaching a substrate to a piezoelectric layer with an acoustic Bragg reflector between the substrate and the piezoelectric layer; and
forming a conductor pattern comprising a plurality of interdigital transducers (IDTs) on the piezoelectric layer,
wherein the plurality of IDTs comprises a first IDT of first acoustic resonator and a second IDT of a second acoustic resonator, and
wherein a first thickness of the piezoelectric layer under the first IDT is greater than a second thickness of piezoelectric layer under the second IDT.
